(19) United States
(12) Patent Application Publication
(10) Pub. No.: US 2013/0102115 A1
(43) Pub. Date: Apr. 25, 2013

(54) METHOD FOR MANUFACTURING ACTIVE MATRIX SUBSTRATE

(71) Applicants: Takeshi Yaneda, Osaka (JP); Hiromitsu Katsui, Osaka (JP); Wataru Nakamura, Osaka (JP)

(72) Inventors: Takeshi Yaneda, Osaka (JP); Hiromitsu Katsui, Osaka (JP); Wataru Nakamura, Osaka (JP)

(73) Assignee: SHARP KABUSHIKI KAISHA, Osaka (JP)

(21) Appl. No.: 13/806,964

(22) PCT Filed: Jul. 1, 2011
(86) PCT No.: PCT/JP2011/065219

§ 371 Date: Dec. 26, 2012

(30) Foreign Application Priority Data
Jul. 8, 2010 (JP) 2010-156011

(51) Int. Cl. H01L 29/66

(52) U.S. Cl. CPC H01L 29/66742
USPC 438/155

(57) ABSTRACT

The disclosed method for manufacturing an active matrix substrate includes a step in which a first mask is used to pattern a first conductive layer G, CS, and S, a step in which a second mask is used to pattern a first insulating layer, a step in which a third mask is used to pattern a semiconductor layer, a step in which a fourth mask is used to pattern a second conductive later, a step in which a fifth mask is used to pattern a second insulating layer, and a step in which a sixth mask is used to pattern a third conductive layer.

### TECHNICAL FIELD

The present invention relates to a method for manufacturing an active matrix substrate used in a display panel such as a liquid crystal panel.

### BACKGROUND ART

In recent years, liquid crystal display devices, for example, are widely used for liquid crystal televisions, monitors, and mobile telephones as a flat panel display having advantages over existing CRT displays such as being thinner and more lightweight. A liquid crystal display device is known in which an active matrix substrate is used in a liquid crystal panel, which is a display panel, the active matrix substrate having: a plurality of source wiring lines (data wiring lines) and a plurality of gate wiring lines (scanning wiring lines) arranged in a matrix; and pixels, arranged in a matrix, having thin film transistors (TFT) as switching elements and pixel electrodes connected to the thin film transistors in the vicinity of the intersections of the source wiring lines and the gate wiring lines.

Also, in the active matrix substrate such as that mentioned above, the gate wiring lines are connected to a gate driver via a terminal, for example. Specifically, in the active matrix substrate, in general, a gate insulating film and a protective layer are formed on gate electrodes of the thin film transistors and gate wiring lines formed integrally with the gate electrodes in that order, and an interlayer insulating film is formed on the protective layer. Also, in the active matrix substrate, by providing an opening (contact hole) in the gate insulating film, the protective layer, and the interlayer insulating film in the contact hole (terminal), the gate wiring lines and the ITO connected to the gate driver were connected to each other, and the gate wiring lines and the gate driver were connected to each other via the ITO.

In the existing active matrix substrate, ITO was deposited over the gate insulating film and the protective layer in the opening. As a result, in the existing active matrix substrate, there were cases in which the ITO experienced disconnections due to the difference in height between the gate insulating film and the protective layer.

To solve this problem, in a conventional active matrix substrate such as that disclosed in Patent Document 1 below, for example, by providing a semiconductor layer between a gate insulating film and a protective layer, the step coverage between the gate insulating film and the protective layer is improved, thus preventing disconnections in the ITO.

The conventional active matrix substrate will be described specifically, with reference to FIGS. 14 and 15.

FIG. 14 is a plan view that shows a terminal provided on the conventional active matrix substrate. FIG. 15 is a cross-sectional view along the line XVII-XVII of FIG. 14.

As shown in FIGS. 14 and 15, a conventional active matrix substrate 80 is provided with a gate wiring line 81 formed on a substrate 80a, and an ITO 82 connected to the gate wiring line 81 via a contact hole. The gate wiring line 81 is made of a three-layered metal film constituted of a titanium film 84a, an aluminum film 84b, and a titanium film 84c formed in this order on the substrate 80a, for example. In the gate wiring line 81, the titanium film 84c is connected directly to the ITO 82 in the opening HO of the contact hole, and corrosion resulting from the ITO 82 and the aluminum film 84b being in contact with each other can be prevented.

Also, in the conventional active matrix substrate 80, a gate insulating film 85, a protective layer 86, and an interlayer insulating film 87 are formed in this order on the titanium film 84c of the gate wiring line 81. Other than the connective portion of the ITO 82 and the titanium film 84c in the opening HO of the contact hole, the ITO 82 and the gate wiring line 81 are insulated by the gate insulating film 85, the protective layer 86, and the interlayer insulating film 87.

In addition, in the conventional active matrix substrate 80, a semiconductor layer 83 is formed between the gate insulating film 85 and the protective layer 86. The semiconductor layer 83 is formed at the same time as a semiconductor layer of a thin film transistor (not shown in drawings) provided in the active matrix substrate 80. By providing the conventional active matrix substrate 80 with the semiconductor layer 83, the step coverage between the gate insulating film 85 and the protective layer 86 was improved. When forming the ITO 82 on the conventional active matrix substrate 80, it was possible to prevent disconnections in the ITO 82 resulting from the difference in height between the gate insulating film 85 and the protective layer 86.

### RELATED ART DOCUMENTS

### Patent Documents

Patent Document 1: Japanese Patent No. 3625598

### SUMMARY OF THE INVENTION

### Problems to be Solved by the Invention

However, with the conventional active matrix substrate 80 mentioned above, the opening HO of the contact hole was formed by etching the gate insulating film 85, the protective layer 86, and the interlayer insulating film 87 together. As a result, as shown in FIG. 15, in the conventional active matrix substrate 80, the faces of the gate insulating film 85, the protective layer 86, and the interlayer insulating film 87 facing the opening HO were at a sharp inclination of almost 90° to the gate wiring line 81. As a result, in the conventional active matrix substrate 80, when forming the ITO 82 by sputtering, for example, an ITO 82 was sometimes not formed to an appropriate degree on parts of each of the above-mentioned faces, thus resulting in disconnections in the ITO 82.

As mentioned above, the conventional active matrix substrate had a problem in that the plurality of conductive layers (the gate wiring line 81 and the ITO 82) that sandwich the insulating layer (the gate insulating film 85, the protective layer 86, and the interlayer insulating film 87) therebetween could not be reliably connected to each other.

With the above-mentioned problem in consideration, an object of the present invention is to provide a method for manufacturing an active matrix substrate that can reliably connect a plurality of conductive layers that sandwich an insulating layer therebetween.

### Means for Solving the Problems

A method for manufacturing an active matrix substrate according to the present invention is a method for manufacturing an active matrix substrate that has a thin film transistor, a first conductive layer, and a second conductive layer and a third conductive layer, which are connected to the first conductive layer, the method including:

patterning the first conductive layer using a first mask;

patterning a first insulating layer that covers the first conductive layer using a second mask so as to form an opening in the first insulating layer that exposes the first conductive layer;

patterning a semiconductor layer that covers the first conductive layer and the first insulating layer using a third mask;

patterning a second conductive layer that covers the first insulating layer using a fourth mask such that the first conductive layer and the second conductive layer are connected in the opening of the first insulating layer;

patterning a second insulating layer that covers the second conductive layer using a fifth mask so as to form an opening in the second insulating layer that exposes a connective portion of the first conductive layer and the second conductive layer; and

patterning a third conductive layer that covers the second insulating layer using a sixth mask such that the second conductive layer and the third conductive layer are connected in the opening of the second insulating layer.

In the above-mentioned manufacturing method, the first mask for patterning the first conductive layer, the second mask for patterning the first insulating layer, the third mask for patterning the semiconductor layer, the fourth mask for patterning the second conductive layer, the fifth mask for patterning the second insulating layer, and the sixth mask for patterning the third conductive layer are used. By patterning each of the layers with the six masks in this manner, the plurality of conductive layers that respectively sandwich insulating layers therebetween can be reliably connected to each other. The first conductive layer can be patterned by etching the first conductive layer using the first mask, for example. Similarly, the first insulating layer can be patterned by etching the first insulating layer using the second mask, the semiconductor layer can be patterned by etching the semiconductor layer using the third mask, the second conductive layer can be patterned by etching the second conductive layer using the fourth mask, the second insulating layer can be patterned by etching the second insulating layer using the fifth mask, and the third conductive layer can be patterned by etching the third conductive layer using the sixth mask.

In the method for manufacturing the active matrix,

in the step of patterning the first conductive layer, a gate electrode of the thin film transistor and an electrical wiring line may be formed,

in the step of patterning the first insulating layer, an opening in the first insulating layer may be formed, and an electrode contact layer may be formed,

in the step of patterning the semiconductor layer, a semiconductor layer of the thin film transistor may be formed, and

in the step of patterning the second conductive layer, the second conductive layer may be formed so as to cover the semiconductor layer, the electrode contact layer, and at least a portion of an edge of the opening in the first insulating layer, such that a source electrode and a drain electrode in the thin film transistor are formed by etching the second conductive layer, and such that the electrical wiring line is connected to the second conductive layer in the opening.

In the above-mentioned manufacturing method, patterning of the electrical wiring line and other parts of the second conductive layer can be conducted at the same time as the patterning of the gate electrode, the source electrode, and the drain electrode of the thin film transistor.

In the method for manufacturing the active matrix,

in the step of patterning the first insulating layer, an opening in the first insulating layer may be formed so as to expose an end of the first conductive layer, and

in the step of patterning the second conductive layer, the second conductive layer may be patterned so as to cover at least a portion of an edge of the opening, and such that the end of the first conductive layer and the second conductive layer are directly connected to each other in the opening.

In the above-mentioned manufacturing method, the terminal of the first conductive layer is provided so as to protrude in the opening formed in the insulating layer, as a result of the first mask and the second mask. Also, as a result of the fourth mask, the second conductive layer is provided so as to cover at least a portion of the edge of the opening, and so as to be connected directly to an end of the first conductive layer in the opening. With this configuration, it is possible to connect the second conductive layer to the first conductive layer without causing disconnections in the second conductive layer. As a result, the plurality of conductive layers sandwiching an insulating layer therebetween can be reliably connected to each other.

In the above-mentioned method for manufacturing the active matrix,

in the step of patterning the second insulating layer, an opening may be formed in the second insulating layer so as to expose an end of the second conductive layer, and

in the step of patterning the third conductive layer, the third conductive layer may be patterned so as to cover at least a portion of an edge of the opening, and such that the end of the second conductive layer and the third conductive layer are directly connected to each other in the opening. With this configuration, it is possible to connect the third conductive layer to the second conductive layer without causing disconnections in the third conductive layer.

In the above-mentioned method for manufacturing the active matrix, an auxiliary capacitance wiring line for generating auxiliary capacitance may be used as the electrical wiring line, an electrode member that connects the auxiliary capacitance wiring line to a driver part to be connected to the auxiliary capacitance wiring line may be used as the second conductive layer, and a connective portion between the auxiliary capacitance wiring line and the electrode member may be formed in the step of patterning the second conductive layer. In this case, it is possible to reliably connect the auxiliary capacitance wiring line to the electrode member.

In the above-mentioned method for manufacturing the active matrix, a gate wiring line connected to the gate electrode of the thin film transistor may be used as the electrical wiring line, an intermediate electrode member connected to the gate wiring line may be used as the second conductive layer, an electrode member connected to a gate driver and to the intermediate electrode member may be used as the third conductive layer, and a gate terminal that connects the gate wiring line to the gate driver may be formed in the step of patterning the third conductive layer. In this case, it is possible to reliably connect the gate wiring line to the intermediate electrode member and to connect the intermediate electrode member to the electrode member.

In the above-mentioned method for manufacturing the active matrix, a source wiring line connected to the source electrode of the thin film transistor may be used as the electrical wiring line, an intermediate electrode member connected to the source wiring line may be used as the second conductive layer, an electrode member connected to a source driver and to the intermediate electrode member may be used as the third conductive layer, and a source terminal that connects the source wiring line to the source driver may be formed in the step of patterning the third conductive layer. In this case, it is possible to reliably connect the source wiring line to the intermediate electrode member and to reliably connect the intermediate electrode member to the electrode member.

In the above-mentioned method for manufacturing the active matrix, an electrode connecting wiring line for connecting the drain electrode of the thin film transistor to a pixel electrode to be connected to the thin film transistor may be formed of the second conductive layer, and a connective portion that connects the electrode connecting wiring line to the pixel electrode may be formed of the third conductive layer. In this case, it is possible to reliably connect the source wiring line to the intermediate electrode member while reliably connecting the intermediate electrode member to the electrode member. In this case, the electrode connecting wiring line and the pixel electrode can be reliably connected to each other.

### Effects of the Invention

The present invention can provide an active matrix substrate in which a plurality of conductive layers that sandwich an insulating layer therebetween can be reliably connected to each other, and manufacturing method therefor.

### BRIEF DESCRIPTION OF THE DRAWINGS

FIG. 1 is a drawing that shows a liquid crystal display device according to an embodiment of the present invention.

FIG. 2 is a drawing that shows a configuration of the liquid crystal panel shown in FIG. 1.

FIG. 3 is a magnified plan view that shows a configuration of main parts of the active matrix substrate shown in FIG. 1.

FIG. 4 is a cross-sectional view of FIG. 3 along the line IV-IV.

FIG. 5 is a cross-sectional view of FIG. 3 along the line V-V.

FIG. 6 is a cross-sectional view of FIG. 3 along the line VI-VI.

FIG. 7 is a cross-sectional view of FIG. 3 along the line VII-VII.

FIG. 8 is a cross-sectional view of FIG. 3 along the line VIII-VIII.

FIG. 9 is a flow chart that shows main manufacturing steps of a main configuration of the active matrix substrate.

FIG. 10 shows manufacturing steps for the thin film transistor shown in FIG. 4 and the connective portion between the auxiliary capacitance wiring line and the electrode member shown in FIG. 5, and FIGS. 10A to 10F show a series of main manufacturing steps.

FIG. 11 shows manufacturing steps for the connective portion between the electrode connecting wiring line and the pixel electrode shown in FIG. 6 and the gate terminal shown in FIG. 7, and FIGS. 11A to 11F show a series of main manufacturing steps.

FIG. 12 is a plan view that shows a configuration of a modification example of a source terminal shown in FIG. 3.

FIG. 13 is a cross-sectional view that shows a configuration of another modification example of the source terminal.

FIG. 14 is a plan view that shows a terminal provided in a conventional active matrix substrate.

FIG. 15 is a cross-sectional view of FIG. 14 along the line XVII-XVII.

### DETAILED DESCRIPTION OF EMBODIMENTS

A preferred embodiment of an active matrix substrate and a manufacturing method therefor according to the present invention will be described below with reference to drawings. In the description below, a case in which the present invention is applied to a transmissive liquid crystal display device will be explained as an example. Also, the dimensions of the components in the drawings do not faithfully represent the actual dimensions of components, the ratio between the dimensions of the components, or the like.

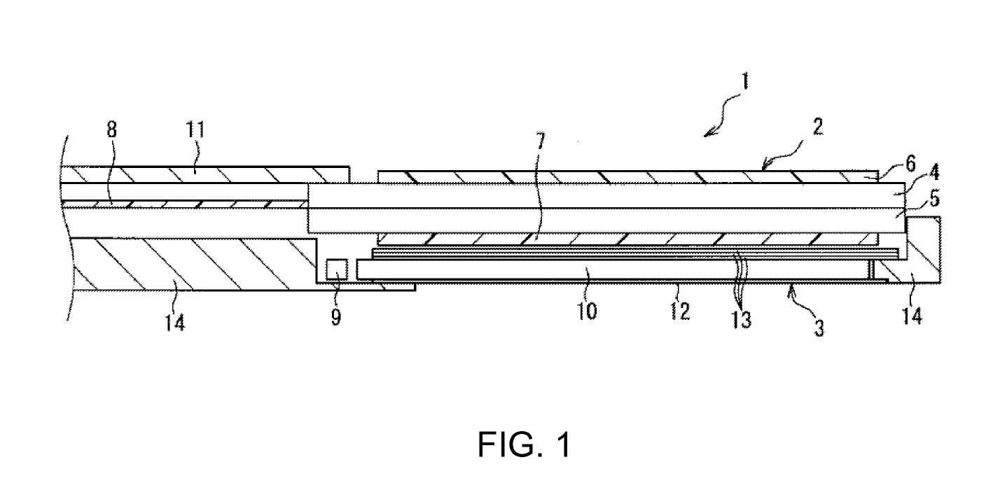

FIG. 1 is a drawing that shows a liquid crystal display device according to one embodiment of the present invention. In FIG. 1, the liquid crystal display device 1 of the present embodiment is provided with a liquid crystal panel 2 disposed such that the viewer side (display side) is on the upper side of FIG. 1, and a backlight device 3 that is disposed on the non-display side (lower side of FIG. 1) of the liquid crystal panel 2 and emits light that illuminates the liquid crystal panel 2.

The liquid crystal panel 2 is provided with a pair of substrates constituted of a color filter substrate 4 and an active matrix substrate 5 of the present invention, and polarizing plates 6 and 7 provided respectively on the outer surfaces of the color filter substrate 4 and the active matrix substrate 5. A liquid crystal layer, which is not shown in drawings, is sandwiched between the color filter substrate 4 and the active matrix substrate 5. A flat transparent glass material or a transparent synthetic resin such as an acrylic resin is used for the color filter substrate 4 and the active matrix substrate 5. The polarizing plates 6 and 7 are made of a resin film such as TAC (triacetyl cellulose) or PVA (polyvinyl alcohol) and are respectively bonded to the color filter substrate 4 and the active matrix substrate 5 so as to cover at least the active display region of the display surface provided in the liquid crystal panel 2.

The active matrix substrate 5 is one substrate of the pair of substrates, and on the active matrix substrate 5, pixel electrodes, thin film transistors (TFTs), and the like are formed between the active matrix substrate 5 and the liquid crystal layer so as to correspond to a plurality of pixels included in the display surface of the liquid crystal panel 2 (details below). The color filter substrate 4 is the other substrate of the pair of substrates and on the color filter substrate 4, a color filter, an opposite electrode, and the like are formed between the color filter substrate 4 and the liquid crystal layer (not shown in drawings).

The liquid crystal panel 2 is provided with an FPC (flexible printed circuit) 8 connected to a control device (not shown in drawings) that conducts drive control of the liquid crystal panel 2, and is configured such that the display surface is driven per pixel unit by operating the liquid crystal layer per pixel unit, thus displaying a desired image in the display surface.

The liquid crystal mode and the pixel configuration of the liquid crystal panel 2 can be appropriately selected. The drive mode of the liquid crystal panel 2 can also be appropriately selected. In other words, any liquid crystal panel that can display data can be used as the liquid crystal panel 2. Thus, in FIG. 1, a detailed configuration of the liquid crystal panel 2 is not shown, and descriptions thereof are also omitted.

The backlight device 3 is provided with a light-emitting diode 9 as a light source, and a light guide plate 10 disposed facing the light-emitting diode 9. Also, in the backlight device 3, the light-emitting diode 9 and the light guide plate 10 are held by a bezel 14, which has an L-shaped cross section, such that the liquid crystal panel 2 is disposed above the light guide plate 10. A case 11 is installed on the color filter substrate 4. With this configuration, the backlight device 3 is installed into the liquid crystal panel 2, and the two components are held as a single unit as a transmissive liquid crystal display device 1 in which illumination light from the backlight device 3 is emitted to the liquid crystal panel 2.

The light guide plate 10 is made of a synthetic resin such as a transparent acrylic resin, and light enters the light guide plate 10 from the light-emitting diode 9. The side of the light guide plate 10 opposite to the liquid crystal panel 2 (opposite surface side) is provided with a reflective sheet 12. The liquid crystal panel 2 side of the light guide plate 10 (light-emitting surface side) is provided with optical sheets 13 such as a lens sheet and a diffusion sheet, and light from the light-emitting diode 9 guided in a prescribed light-guide direction through the light guide plate 10 (left to right in FIG. 1) is provided to the liquid crystal panel 2 after being converted to a planar illumination light with an even brightness.

In the above description, a configuration was described in which an edge light-type backlight device 3 having a light guide plate 10 is used, but the present embodiment is not limited thereto, and a direct-lighting type backlight device may be used. Also, a backlight device having a light source other than a light-emitting diode such as a cold cathode fluorescent tube or a hot cathode fluorescent tube can be used.

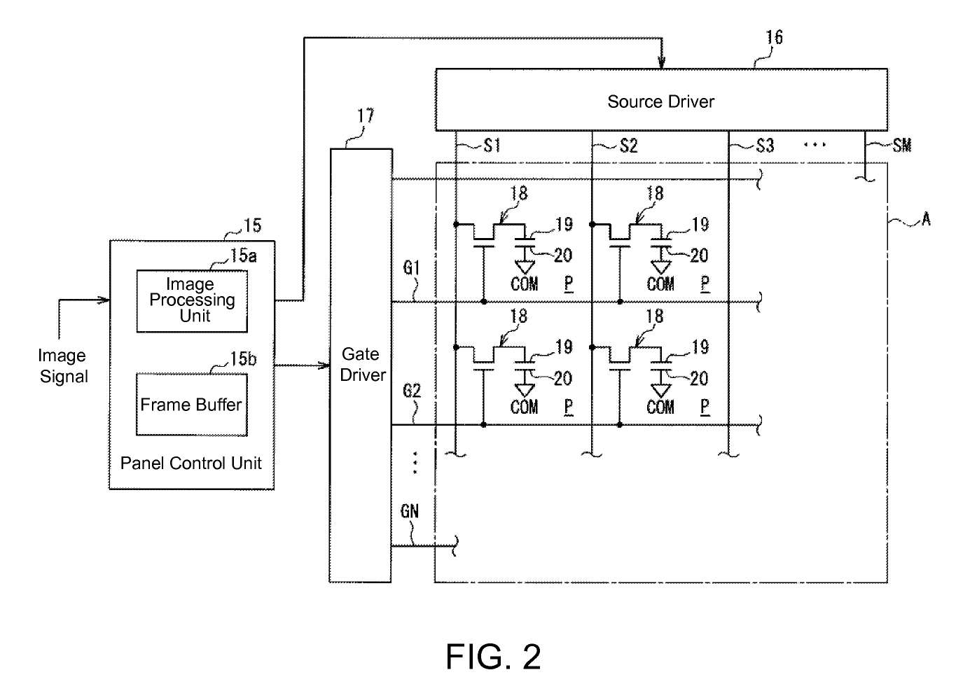

Next, the liquid crystal panel 2 of the present embodiment will be described in detail with reference to FIG. 2.

FIG. 2 is a drawing that shows a configuration of the liquid crystal panel shown in FIG. 1.

In FIG. 2, the liquid crystal display device 1 (FIG. 1) is provided with a panel control unit 15 that conducts drive control of the liquid crystal panel 2 (FIG. 1), which functions as the display part that displays data such as characters and images, and a source driver 16 and a gate driver 17, which operate based on command signals from the panel control unit 15.

The panel control unit 15 is provided in the control device and is designed so as to allow image signals to be inputted from outside the liquid crystal display device 1. The panel control unit 15 is provided with an image processing unit 15a that generates various command signals to the source driver 16 and the gate driver 17 after conducting a prescribed image processing to the inputted image signal, and a frame buffer 15b that can store one frame of display data included in the inputted image signal. The panel control unit 15 conducts drive control on the source driver 16 and the gate driver 17 based on the inputted image signal, and thus, data corresponding to the image signal is displayed in the liquid crystal panel 2.

The source driver 16 and the gate driver 17 are disposed on the active matrix substrate 5. Specifically, the source driver 16 is disposed on the surface of the active matrix substrate 5 along the horizontal direction of the liquid crystal panel 2 outside of an active display region A of the liquid crystal panel 2, which functions as a display panel. The gate driver 17 is disposed on the surface of the active matrix substrate 5 along the vertical direction of the liquid crystal panel 2 outside of the active display region A.

Also, the source driver 16 and the gate driver 17 are driver circuits that drive each of the plurality of pixels P provided on the liquid crystal panel 2 side, and the source driver 16 and the gate driver 17 are respectively connected to a plurality of source wiring lines S1 to SM (M being an integer of at least 2; hereinafter collectively referred to as “S”), and a plurality of gate wiring lines G1 to GN (N being an integer of at least 2; hereinafter collectively referred to as “G”). The source wiring lines S and the gate wiring lines G are respectively configured as data wiring lines and scanning wiring lines and are arranged in a matrix so as to intersect with each other on a substrate made of a transparent glass material or a transparent synthetic resin material (not shown in drawings) included in the active matrix substrate 5. In other words, the source wiring lines S are provided on the substrate so as to be parallel in the column direction of the matrix (vertical direction of the liquid crystal panel 2), and the gate wiring lines G are provided on the substrate so as to be parallel in the row direction of the matrix (horizontal direction of the liquid crystal panel 2).

Auxiliary capacitance wiring lines for generating auxiliary capacitance are connected to the source driver 16, as will be described below, and the source driver 16 is configured so as to also function as a driver part for generating auxiliary capacitance.

The pixels P that respectively include thin film transistors 18, which are switching elements, and pixel electrodes 19 connected to the thin film transistors 18 are provided in the vicinity of the respective intersections of the source wiring lines S and the gate wiring lines G. A common electrode 20 is configured so as to face the respective pixel electrodes 19 in the pixels P through the liquid crystal layer provided in the liquid crystal panel 2. In other words, in the active matrix substrate 5, each pixel is constituted of a thin film transistor 18, a pixel electrode 19, and a common electrode 20.

Also, in the active matrix substrate 5, each of the regions that are bordered by the source wiring lines S and the gate wiring lines G in a matrix is a region in which each of the plurality of pixels P is provided. The plurality of pixels P include red (R), green (G), and blue (B) sub-pixels. The RGB sub-pixels are sequentially disposed in this order, for example, in parallel with each of the gate wiring lines G1 to GN. In addition, the RGB sub-pixels can display the corresponding colors using the color filter layer (not shown in drawings) provided on the side of the color filter substrate 4.

Also, in the active matrix substrate 5, the gate driver 17 sequentially outputs a scanning signal (gate signal) to the gate wiring lines G1 and GN based on command signals from the image processing unit 15a in order to turn on the gate electrodes of the corresponding thin film transistors 18. The source driver 16 outputs data signals (voltage signals (gradation voltages)) that correspond to the brightness (gradation) of the displayed image to the corresponding source wiring lines S1 to SM, based on command signals from the image processing unit 15a.

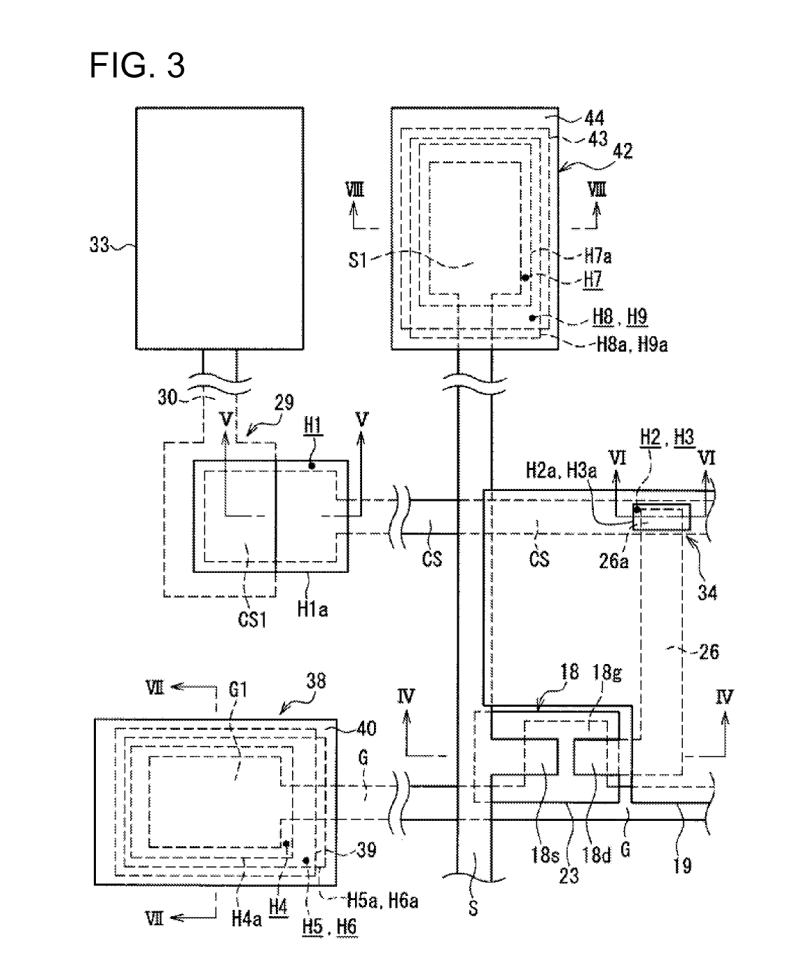

Next, main components of the active matrix substrate 5 of the present embodiment will be described in detail with reference to FIGS. 3 to 8.

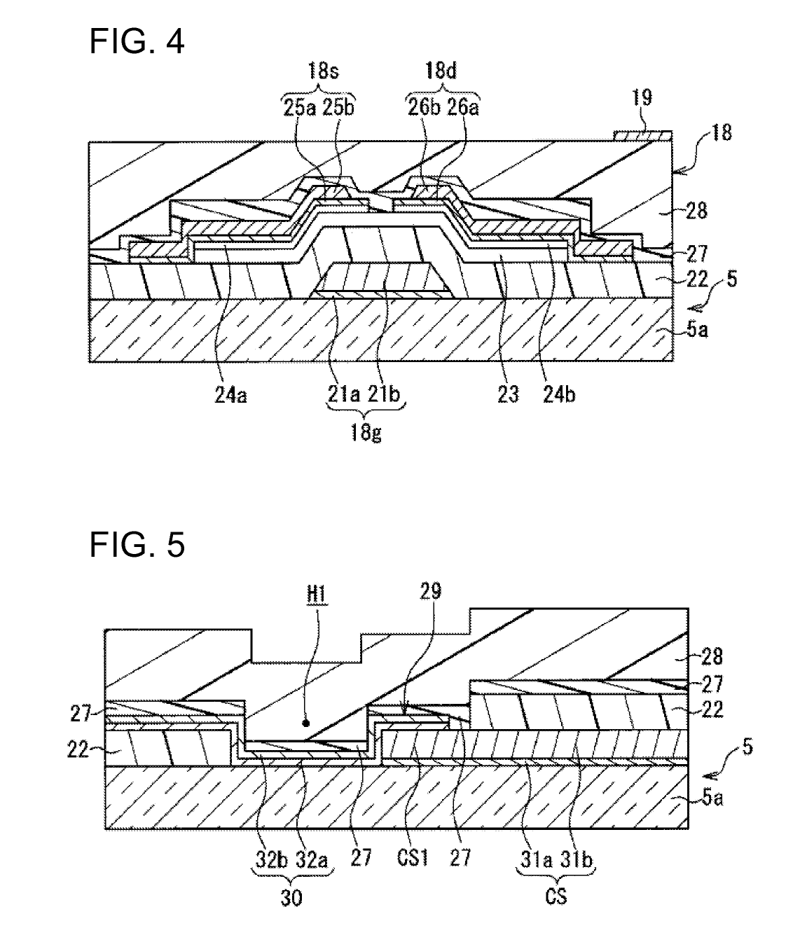

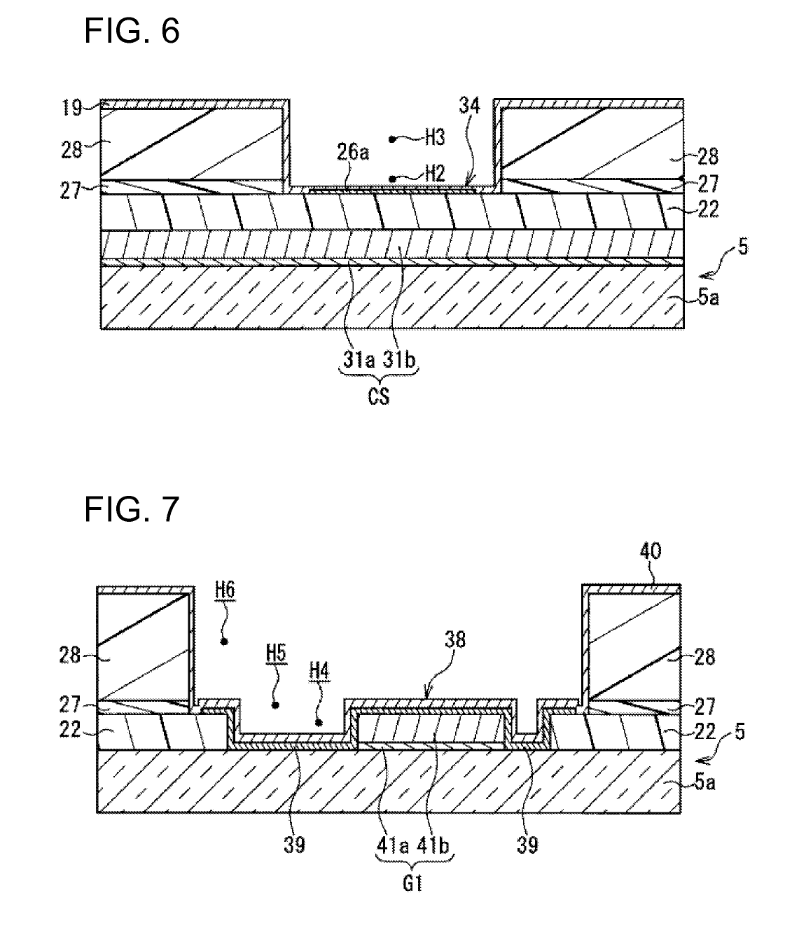

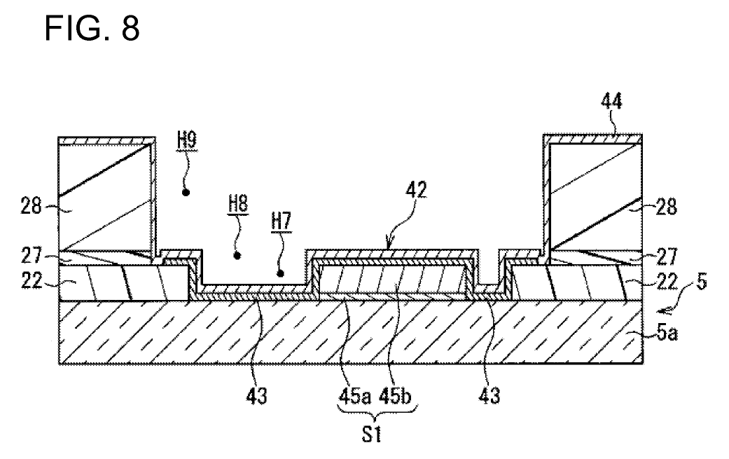

FIG. 3 is a magnified plan view that shows main components of the active matrix substrate shown in FIG. 1. FIG. 4 is a cross-sectional view of FIG. 3 along the line IV-IV. FIG. 5 is a cross-sectional view of FIG. 3 along the line V-V. FIG. 6 is a cross-sectional view of FIG. 3 along the line VI-VI. FIG. 7 is a cross-sectional view of FIG. 3 along the line VII-VII. FIG. 8 is a cross-sectional view of FIG. 3 along the line VIII-VIII.

In FIG. 3, the active matrix substrate 5 of the present embodiment is provided with the thin film transistor 18 in the vicinity of the intersection of the gate wiring line G and the source wiring line S. The thin film transistor 18 is provided with a gate electrode 18g formed integrally with the gate wiring line G, a source electrode 18s formed integrally with the source wiring line S, a drain electrode 18d provided so as to face the source electrode 18s, and an amorphous silicon layer 23 as a semiconductor layer. Also, the gate wiring line G and the gate electrode 18g are made of a three-layered metal film, for example, and the source wiring line S, the source electrode 18s, and the drain electrode 18d are made of a two-layered metal film, for example (details below).

Also, the drain electrode 18d is formed at one end of the electrode connecting wiring line 26 for connecting the drain electrode 18d to the pixel electrode 19. The other end of the electrode connecting wiring line 26 is connected to the pixel electrode 19 in the openings H2 and H3 in the contact hole as a connective portion 34 provided above an auxiliary capacitance wiring line CS as will be described below.

The auxiliary capacity wiring line CS is a wiring line for generating a prescribed auxiliary capacitance for each pixel, and is provided so as to be parallel to the gate wiring line G. Also, the auxiliary capacitance wiring line CS is made of the same three-layered metal film as the gate wiring line G, for example, and an end CS1 of the auxiliary capacitance wiring line CS is connected to an electrode member 30 in an opening H1 in the contact hole, which functions as a connective portion 29 of the end CS1. The electrode member 30 is connected to the source driver 16 as a driver part via a terminal 33.

Also, in the gate wiring line G, an end G1 thereof is connected to the gate driver 17 via the gate terminal 38. Specifically, in the gate terminal 38, the end G1 of the gate wiring line G and the intermediate electrode member 39, which is to be connected to the gate wiring line G, are connected to each other in an opening H4 in the contact hole in the gate terminal 38. In addition, in the openings H5 and H6 in the contact hole, the intermediate electrode member 39 and the electrode member 40, which is connected to the gate driver 17, are connected to each other (details below). The electrode member 40 is constituted of the same transparent conductive film (ITO, for example) as the pixel electrode 19.

In the source wiring line S, an end S1 thereof is connected to the source driver 16 via the source terminal 42. Specifically, in the source terminal 42, the end S1 of the source wiring line S and the intermediate electrode member 43, which is to be connected to the source wiring line S, are connected to each other in the opening H7 in the contact hole. In addition, the intermediate electrode member 43 and the electrode member 44, which is connected to the source driver 16, are connected to each other in the openings H8 and H9 in the contact hole (details below). The electrode member 44 is constituted of the same transparent conductive film (ITO, for example) as the pixel electrode 19.

Specifically, as shown in FIG. 4, in the thin film transistor 18, a gate electrode 18g constituted of a titanium film 21a and a copper film 21b, for example, is provided on the substrate 5a of the active matrix substrate 5. Also, the gate insulating film 22 is provided so as to cover the gate electrode 18d, and an amorphous silicon layer 23 and electrode contact layers 24a and 24b are formed on the gate insulating film 22. The gate insulating film 22 is made of a silicon nitride (SiNₓ), for example. Also, the electrode contact layers 24a and 24b are made of n+ amorphous silicon, for example.

A source electrode 18s constituted of a titanium film 25a and an aluminum film 25b, for example, is formed on the electrode contact layer 24a, and the source electrode 18s is connected to a source region of the amorphous silicon layer 23 via the electrode contact layer 24a. A drain electrode 18d constituted of a titanium film 26a and an aluminum film 26b, for example, is formed on the electrode contact layer 24b, and the drain electrode 18d is connected to a drain region of the amorphous silicon layer 23 via the electrode contact layer 24b. Also, in the amorphous silicon layer 23, a channel region is formed between the source region and the drain region. The electrode contact layers 24a and 24b are not formed above the channel region, and a prescribed gap is formed therein.

In the thin film transistor 18, the protective layer 27 and the interlayer insulating film 28 are formed in this order so as to cover the source electrode 18s and the drain electrode 18d. The protective layer 27 is made of a silicon nitride (SiNₓ), for example. The interlayer insulating film 28 is made of a photosensitive interlayer insulating film material in which an insulating material such as a novolac resin is mixed with a photosensitive material.

As shown in FIG. 5, in the connective portion 29, the auxiliary capacitance wiring line CS made of a titanium film 31a and a copper film 31b, for example, is provided on the substrate 5a. In the connective portion 29, the auxiliary capacitance wiring line CS constitutes the first conductive layer, and the end CS1 thereof is provided so as to protrude in the opening H1 provided in the gate insulating film 22, which is an example of the first insulating layer. In the connective portion 29, the electrode member 30, which is one example of the second conductive layer, is connected directly to the end CS1 of the auxiliary capacitance wiring line CS in the opening H1. The electrode member 30 is made of a titanium film 32a and an aluminum film 32b, for example, and as shown in FIG. 3, the electrode member 30 is provided so as to cover at least a portion of an edge H1a of the opening H1.

As shown in FIG. 6, in the connective portion 34, the end of the electrode connecting wiring line 26, which is one example of the second conductive layer, is provided so as to protrude in the openings H2 and H3 provided respectively in the protective layer 27 and the interlayer insulating film 28, which function as the second insulating layer. In other words, in the openings H2 and H3, the titanium film 26a, which is an end of the electrode connecting wiring line 26, is formed on the gate insulating film 22 so as to protrude. Below the gate insulating film 22, the auxiliary capacitance wiring line CS, which is one example of the first conductive layer, is formed on the substrate 5a. Also, in the connective portion 34 the pixel electrode 19, which is one example of the third conductive layer, is connected directly to the end (titanium film 26a) of the electrode connecting wiring line 26 in the openings H2 and H3. The pixel electrode 19 is made of ITO, for example, and as shown in FIG. 3, is provided so as to cover at least a portion of the edges H2a and H3a of the openings H2 and H3.

In the present embodiment, auxiliary capacitance was formed by the electrode connecting wiring line 26, the gate insulating film 22, and the auxiliary capacitance wiring line CS, but auxiliary capacitance may be formed by the pixel electrode 19, the gate insulating film 22, and the auxiliary capacitance wiring line CS, by the pixel electrode 19, the protective layer 27, the gate insulating film 22, and the auxiliary capacitance wiring line CS, or by the pixel electrode 19, the interlayer insulating film 28, the protective layer 27, the gate insulating film 22, and the auxiliary capacitance wiring line CS. In these alternate cases, the connective portion 34 does not need to be provided above the auxiliary capacitance wiring line CS.

As shown in FIG. 7, in the gate terminal 38, the end G1 of the gate wiring line G constituted of a titanium film 41a and a copper film 41b, for example, is provided on the substrate 5a. In the gate terminal 38, as one example, the gate wiring line G constitutes the first conductive layer, and the end G1 thereof is provided so as to protrude in the opening H4 provided in the gate insulating film 22, which functions as the first insulating layer. In the gate terminal 38, the intermediate electrode member 39, which functions as the second conductive layer, is directly connected to the end G1 of the gate wiring line G in the opening H4. The intermediate electrode member 39 is constituted of a titanium film, for example, and as shown in FIG. 3, is provided so as to cover at least a portion of the edge H4a of the opening H4.

Also, in the gate terminal 38, the electrode member 40, which is one example of the third conductive layer, is directly connected to the intermediate electrode member 39 in the openings H5 and H6, which are respectively provided in the protective layer 27 and the interlayer insulating film 28, which are examples of the second insulating layer. The electrode member 40 is constituted of ITO, for example, and as shown in FIG. 3, is provided so as to cover at least a portion of the edges H5a and H6a of the openings H5 and H6.

As shown in FIG. 8, in the source terminal 42, the end S1 of the source wiring line S constituted of a titanium film 45a and a copper film 45b, for example, is provided on the substrate 5a. In the source terminal 42, as one example, the source wiring line S constitutes the first conductive layer, and the end S1 thereof is provided so as to protrude in the opening H7 provided on the gate insulating film 22, which functions as the first insulating layer. In other words, a gate/source switching portion, which is not shown in the drawings, is connected to the source terminal 42, and in the gate/source switching portion, the source wiring line S, which is provided in a layer above the gate wiring line G in other sections on the substrate 5a, is provided in the same layer as the gate wiring line G on the substrate 5a. In the source terminal 42, the end S1 of the source wiring line S is formed on the substrate 5a.

Also, in the source terminal 42, the intermediate electrode member 43, which is one example of the second conductive layer, is directly connected to the end S1 of the source wiring line S in the opening H7. The intermediate electrode member 43 is constituted of a titanium film, for example, and as shown in FIG. 3, is provided so as to cover at least a portion of the edge H7a of the opening H7.

Also, in the source terminal 42, the electrode member 44, which is an example of the third conductive layer, is directly connected to the intermediate electrode member 43 in the openings H8 and H9 provided respectively in the protective layer 27 and the interlayer insulating film 28, which are examples of the second insulating layer. The electrode member 44 is constituted of ITO, for example, and as shown in FIG. 3, is provided so as to cover at least a portion of the edges H8a and H9a of the openings H8 and H9.

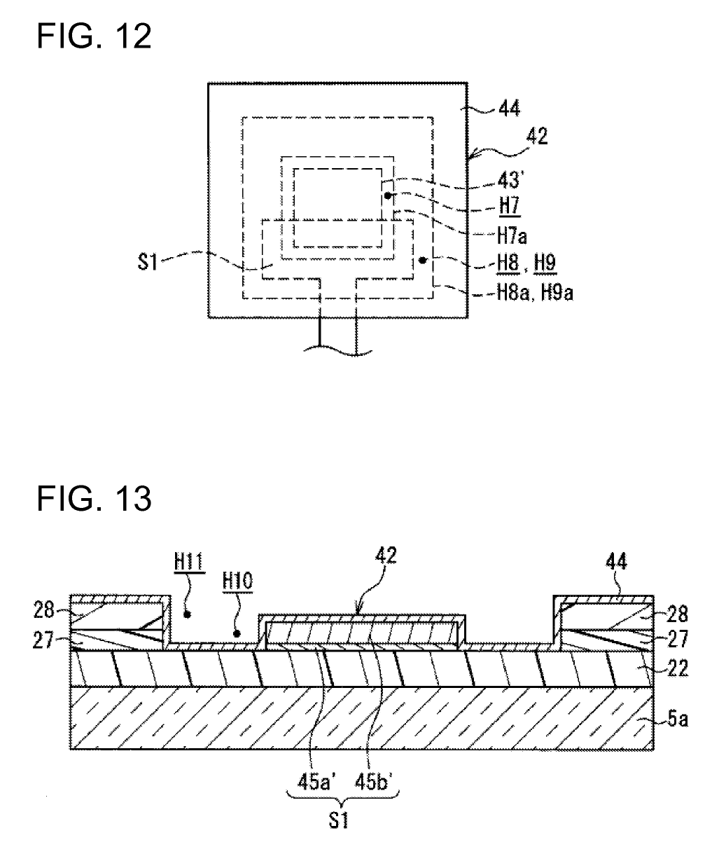

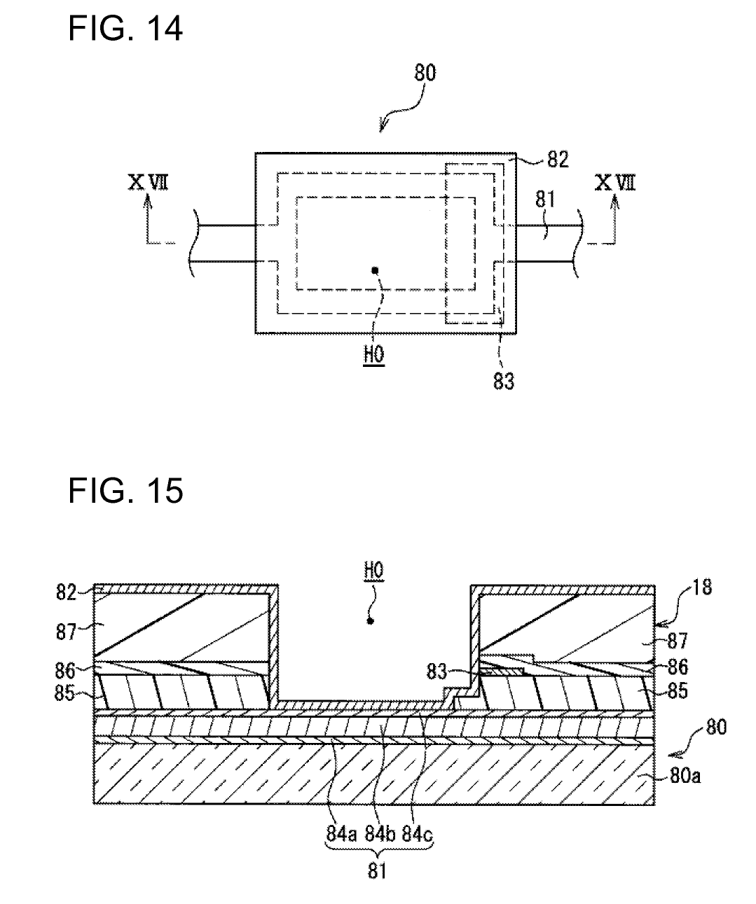

As shown in FIG. 12, the source terminal 42, for example, can be configured differently from what was described above. In this configuration, the source terminal 42 can be configured without the need for the gate/source switching portion. Specifically, in FIG. 12, in the source terminal 42, an electrode member 43′, which functions as the first conductive layer, is provided in the opening H7. The electrode member 43′ is made of a three-layered metal film constituted of a titanium film, an aluminum film, and a titanium film, for example. Also, the end S1 of the source wiring line S, which functions as the second conductive layer, is connected to the electrode member 43′ in the opening H7. The end S1 is made of a two-layered metal film constituted of a titanium film and an aluminum film, for example, and is provided so as to cover at least a portion of the edge H7a of the opening H7. As will be described below, in the electrode member 43′ exposed at the openings H8 and H9, the aluminum film is selectively wet-etched, leaving only the titanium film remaining. Also, in the source terminal 42, the electrode member 44, which functions as the third conductive layer, is directly connected to the end S1 of the source wiring line S and the electrode member 43′ in the openings H8 and H9 provided respectively in the protective layer 27 and the interlayer insulating film 28, which function as the second insulating layer. The electrode member 44 is made of ITO, for example, and as shown in FIG. 12, is provided so as to cover at least a portion of the edges H8a and H9a of the openings H8 and H9.

As shown in FIG. 13, for example, the source terminal 42 can be configured differently from what was described above. Specifically, in FIG. 13, in the source terminal 42, the end S1 of the source wiring line S, which is an example of the first conductive layer, is provided so as to protrude in the openings H10 and H11 provided respectively in the protective layer 27 and the interlayer insulating film 28, which are insulating layers. The end S1 of the source wiring line S is made of a titanium film 45a′ and a copper film 45b′, for example. Also, in the source terminal 42, the electrode member 44, which functions as the second conductive layer, is connected to the end S1 of the source wiring line S in the openings H10 and H11. The electrode member 44 is made of ITO, for example, and is provided so as to cover at least a portion of the edges of the openings H10 and H11.

In a manner similar to the source terminal 42, the terminal 33 is provided with an intermediate electrode member and an electrode member, and the electrode member 30 is connected to the source driver 16 via the intermediate electrode member and the electrode member.

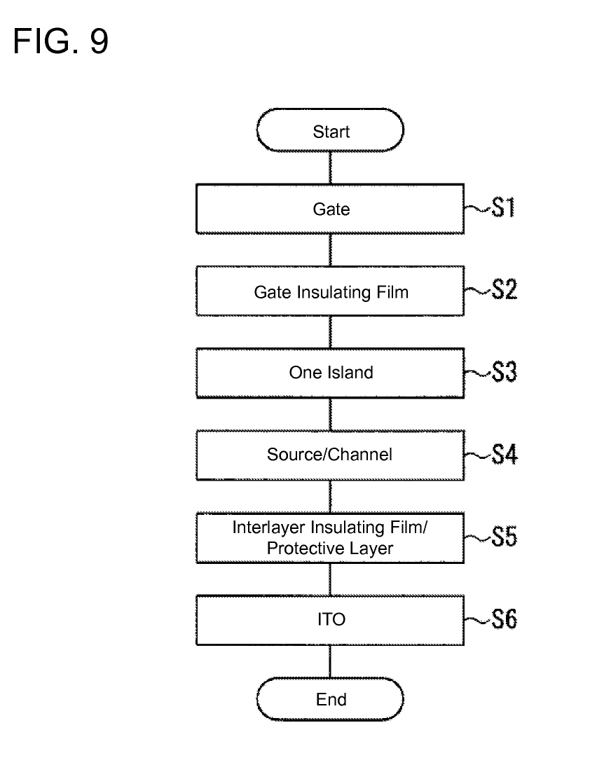

Below, manufacturing methods of main components of the active matrix substrate 5 of the present embodiment, which is configured as described above, will be described in detail with reference to FIGS. 9 to 13.

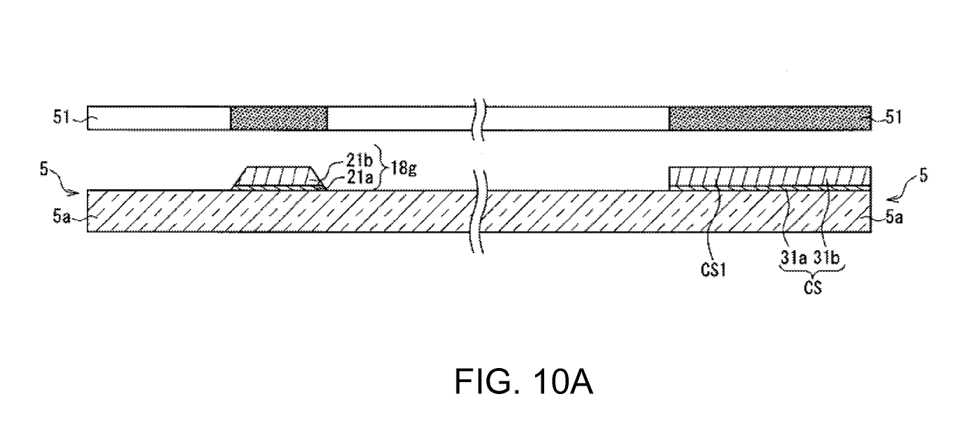

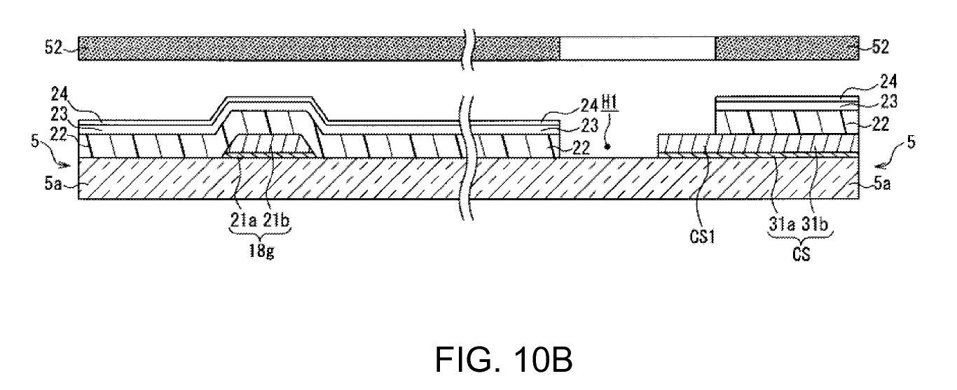

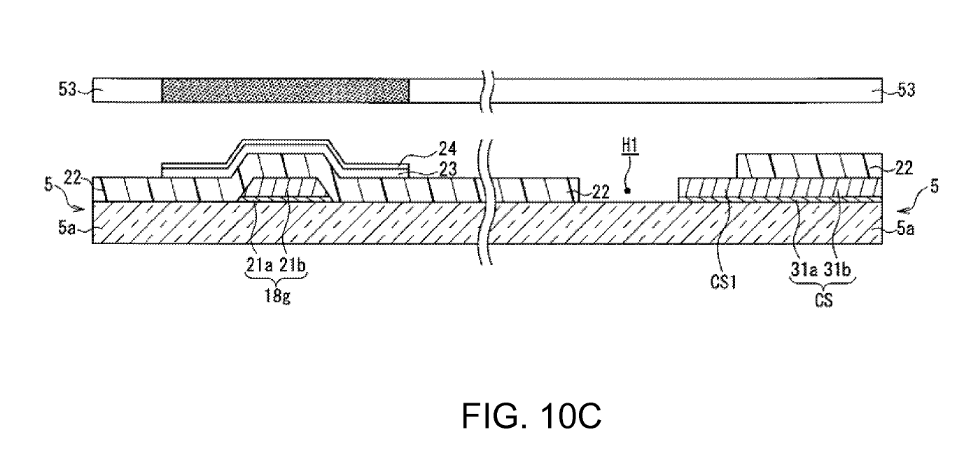

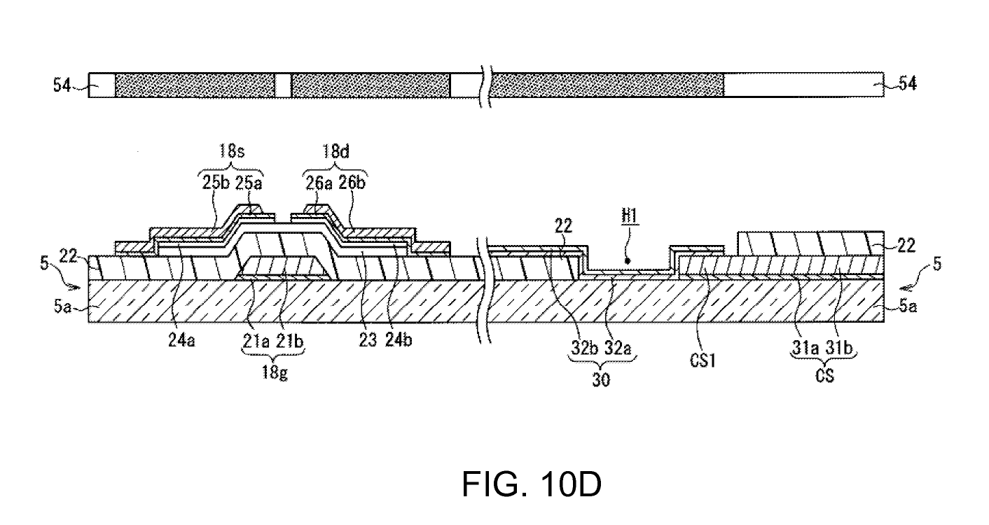

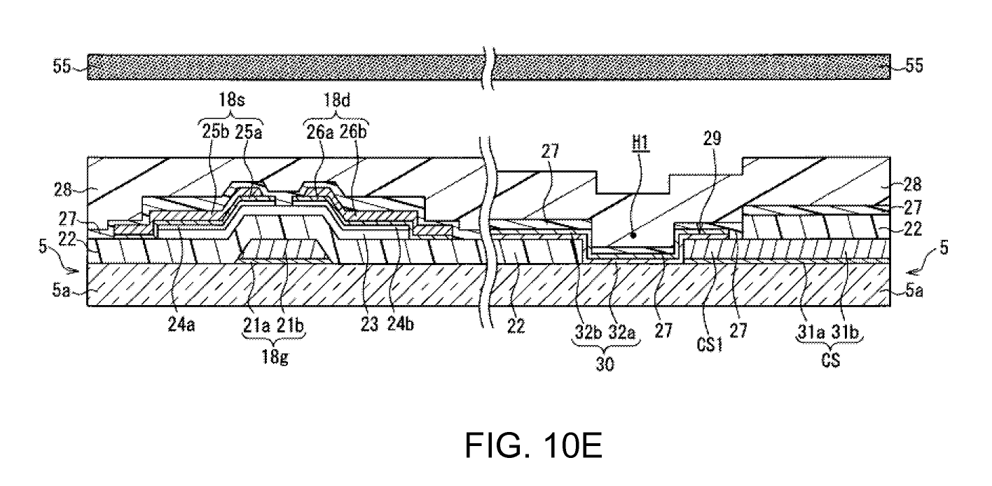

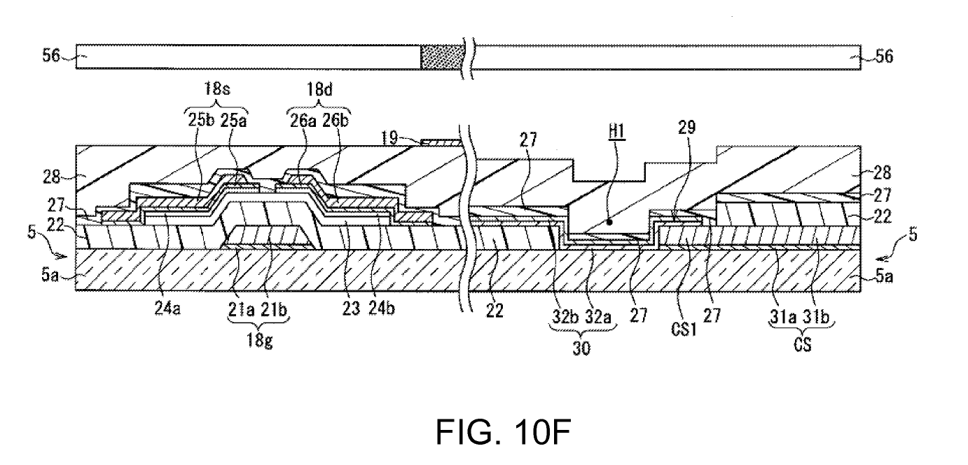

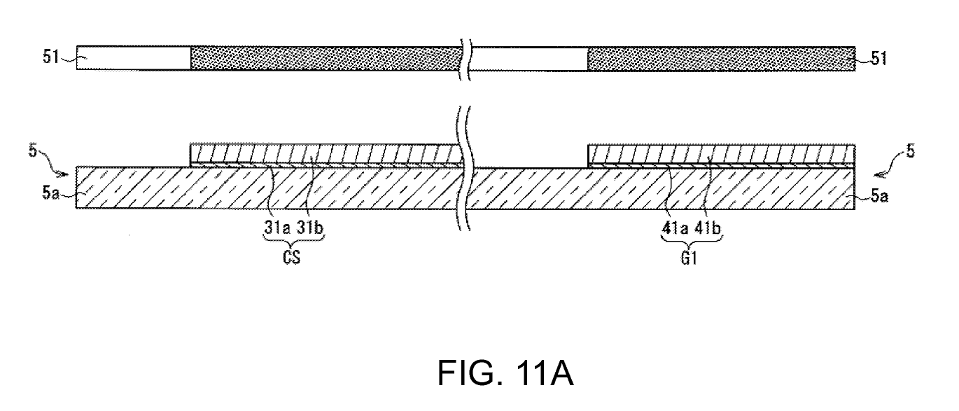

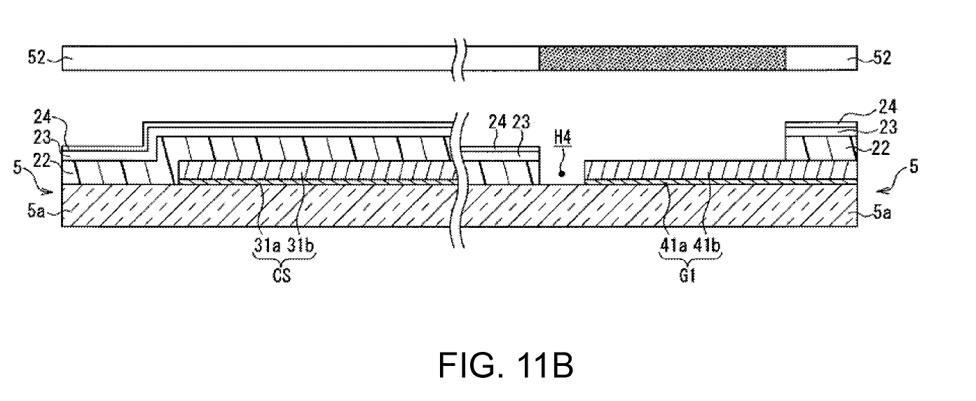

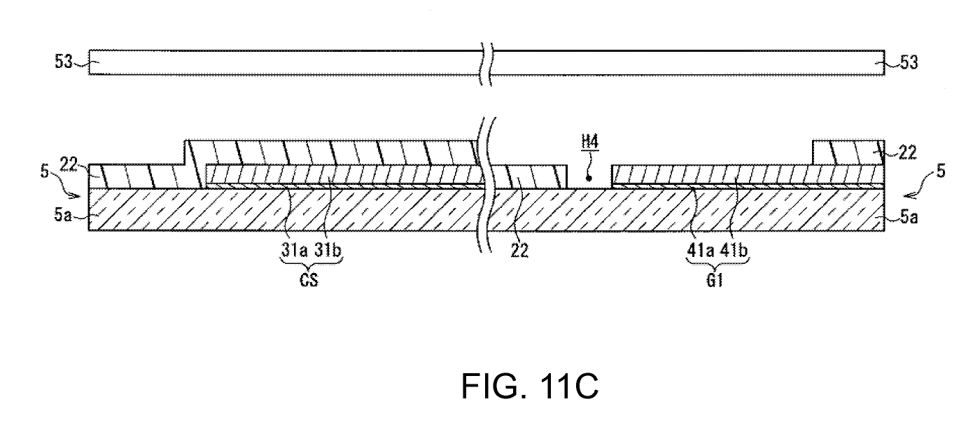

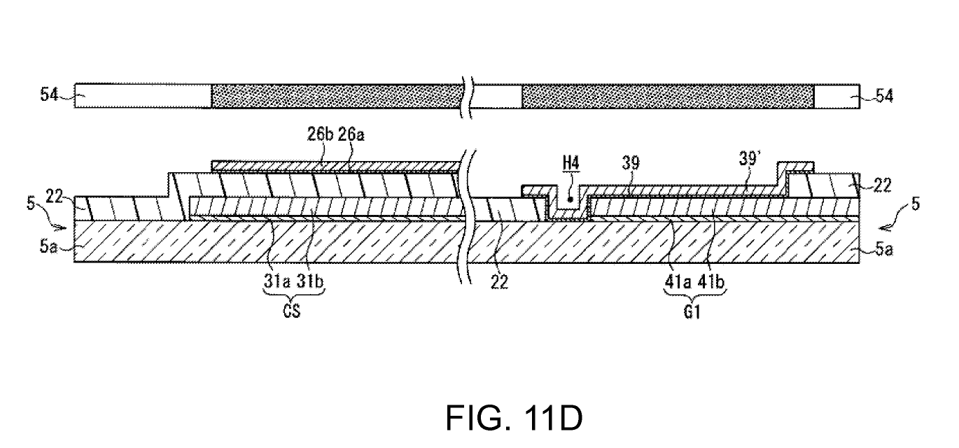

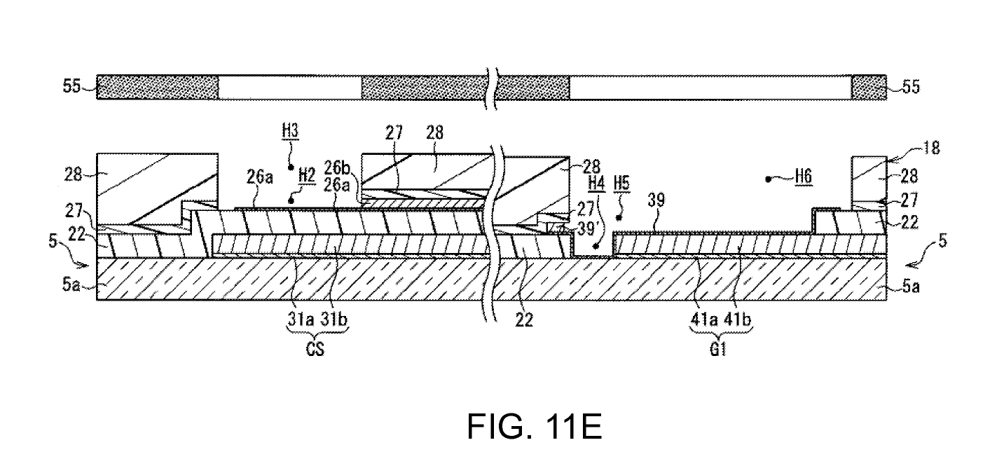

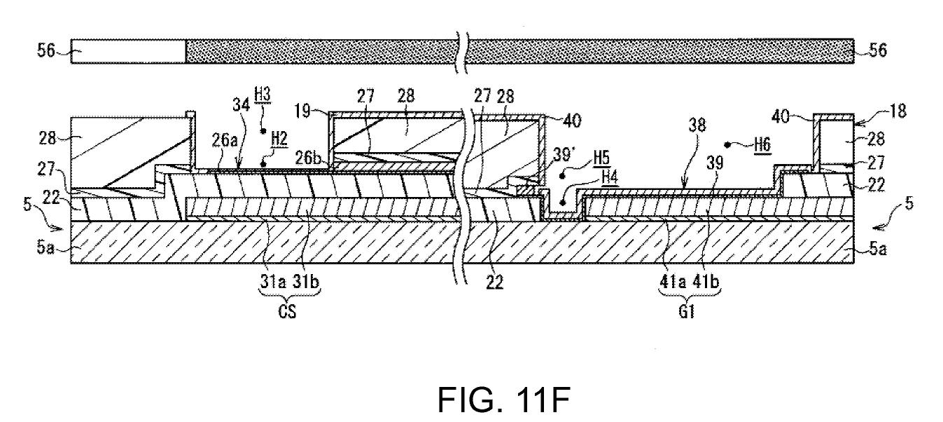

FIG. 9 is a flow chart that shows main manufacturing steps of the main components of the active matrix substrate. FIG. 10 shows the manufacturing steps of the thin film transistor shown in FIG. 4 and the connective portion shown in FIG. 5 between the auxiliary capacitance wiring line and the electrode member. FIGS. 10A to 10F show a series of main manufacturing steps. FIG. 11 shows manufacturing steps of the connective portion shown in FIG. 6 between the electrode connecting wiring line and the pixel electrode, and the gate terminal shown in FIG. 7. FIGS. 11A to 11F show a series of main manufacturing steps. In the description below, steps of forming the source terminal 42 that are similar to those of the gate terminal 38 are omitted for ease of description.

### S1: Step of Forming First Conductive Layer

As shown in step S1 of FIG. 9, in the active matrix substrate 5 of the present embodiment, the gate electrode 18g, which is one example of the first conductive layer, is formed first.

Specifically, as shown on the left side of FIG. 10A, a titanium (Ti) film 21a and a copper (Cu) film 21b are deposited in that order from the bottom onto a substrate 5a made of a transparent insulating substrate such as a glass substrate by sputtering, for example. Then, patterning is conducted thereon by photolithography, wet etching, and resist removal and cleaning, thus forming the gate electrode 18g, which is constituted of the titanium film 21a and the copper film 21b.

During patterning, a first mask is used in order to control the pattern of the gate electrode 18g. Specifically, the titanium film 21a and the copper film 21b are completely covered by a photosensitive organic resist before patterning is conducted, and light is radiated through the first mask 51 (exposure). As a result, the part of the resist to be removed by etching is exposed to light. When placed in developer, the exposed part of the resist is dissolved. Then, the titanium film 21a and the copper film 21b are etched, and resist removal and cleaning is conducted, which leaves the patterned gate electrode 18g remaining on the substrate 5a.

Patterning using the second to sixth masks, which will be described below, can be conducted similarly to what was described above. Also, the specific steps for patterning using a mask are not limited to the above examples. For example, the above example uses a positive resist in which the part of the resist exposed to light is dissolved, but a negative resist in which the part of the resist exposed to light remains can also be used.

Also, as shown respectively on the right side of FIG. 10A and the left side of FIG. 11B, the auxiliary capacitance wiring line CS made of the titanium film 31a and the copper film 31b is formed on the substrate 5a in the connective portions 29 and 34 at the same time as the gate electrode 18g. In addition, as shown in the right side of FIG. 11B, the end G1 of the gate wiring line G made of the titanium film 41a and the copper film 41b is formed in the gate terminal 38 at the same time as the gate electrode 18g. In this manner, patterning can be conducted simultaneously on the gate electrode 18g, the auxiliary capacitance wiring line CS, and the gate terminal 38, using the first mask.

In other words, the titanium films 21a, 31a, and 41a, and the copper films 21b, 31b, and 41b are each deposited and patterned into a prescribed shape simultaneously. In other words, the step shown in FIGS. 10A and 11A is the step of forming the first conductive film, in which after the first conductive layer (auxiliary capacitance wiring line CS and gate wiring line G) is formed on the substrate, patterning is conducted on the first conductive layer using the first mask, by which the gate electrode 18g of the thin film transistor 18 and other electrical wiring lines (auxiliary capacitance wiring line CS and gate wiring line G) are formed.

The specific thickness of the titanium films 21a, 31a, and 41a, which are lower layers, can be set to 30 to 150 nm, for example. The specific thickness of the aluminum films 21b, 31b, and 41b, which are upper layers, can be set to 200 to 500 nm, for example.

It is possible to use a metal such as molybdenum or aluminum, and preferably a metal that can be wet-etched and is not susceptible to corrosion, instead of the titanium films 21a, 31a, and 41a and the copper films 21b, 31b, and 41b in the above description. Also, a two-layered metal film constituted of a titanium film and an aluminum film, a titanium film and a copper film, or a molybdenum film and a copper film may be used, for example. In addition, a three-layered metal film constituted of a titanium film, an aluminum film, and a titanium film may be used, for example. Alternatively, an alloy such as TiMo or MoNb may be used as a two- or three-layered base film or a three-layered upper film, for example.

### S2: Step of Forming First Insulating Layer

Next, as shown in step S2 of FIG. 9, the gate insulating film 22, which is one example of the first insulating layer, and a semiconductor layer of the thin film transistor 18 are formed.

Specifically, as shown in FIG. 10B, the gate insulating film 22, which is made of a silicon nitride (SiNₓ), is formed by the CVD method, for example, so as to cover the gate electrode 18g and the substrate 5a. The amorphous silicon layer 23, which functions as the first semiconductor layer, and the electrode contact layer 24 made of n+ amorphous silicon, which functions as the second semiconductor layer, are formed on the gate insulating film 22 in this order by the CVD method, for example. The gate insulating film 22, the amorphous silicon layer 23, and the electrode contact layer 24 are formed on the entire surface of the substrate 5a. In other words, by conducting the steps of forming the gate insulating film 22, the amorphous silicon layer 23, and the electrode contact layer 24, the first insulating layer (gate insulating film 22), the first semiconductor layer (amorphous silicon layer 23), and the second semiconductor layer (electrode contact layer 24) are formed in this order so as to cover the gate electrode 18g and the electrical wiring lines.

The specific thickness of the gate insulating film 22 can be set to 200 to 500 nm, for example. The specific thickness of the amorphous silicon layer 23 can be set to 30 to 300 nm, for example. The electrode contact layer 24 is doped with an n-type impurity at a high concentration, for example, and the specific thickness thereof can be set to 50 to 150 nm, for example. The deposition temperature of the gate insulating film 22, the amorphous silicon layer 23, and the electrode contact layer 24 can be set to 200 to 300° C., for example.

Etching is conducted on the gate insulating film 22, the amorphous silicon layer 23, and the electrode contact layer 24, which are formed over the entire surface of the substrate 5a in the manner described above, using the second mask 52, to pattern openings (holes). Specifically, by radiating light through the second mask onto a resist formed over the entirety of the electrode contact layer 24, only parts corresponding to the opening H1 (right side of FIG. 10B) and the opening H4 (right side of FIG. 11B) are exposed to light. Then, developing, dry etching, and resist removal and cleaning are conducted, thus removing the parts of the amorphous silicon layer 23 and the electrode contact layer 24 exposed to light, thus forming the opening H1 and the opening H4 in the gate insulating film 22. In other words, the parts of the gate insulating film 22, the amorphous silicon layer 23, and the electrode contact layer 24 where the opening H1 and the opening H4 are to be formed are removed, and the end CS1 of the auxiliary capacitance wiring line CS and the end G1 of the gate wiring line G are exposed.

As shown in FIG. 10B, by the step of forming the opening H1, the end CS1 of the auxiliary capacitance wiring line (first conductive layer) CS is exposed in the opening H1. Similarly, as shown in the right side of FIG. 11B, by the step of forming the opening H4, the end G1 of the gate wiring line (first conductive layer) G is exposed in the opening H4. As a result, even if each first conductive layer is thinned by the developer, the remover, and the like in the photolithography step, the first conductive layer can reliably connect to the corresponding second conductive layer to be mentioned below. This is particularly effective when using a metal with a relatively high susceptibility to corrosion, such as copper. In this manner, in the present embodiment, it is possible to provide connections and terminals that can realize reliable conduction for the various metal films.

### S3: Step of Forming Semiconductor

Next, as shown in step S3 in FIG. 9, one island of the thin film transistor 18, which is an example of a semiconductor layer, is formed.

The amorphous silicon layer 23 and the electrode contact layer 24 are patterned using the third mask, for example. As a result, as shown in the left side of FIG. 10C, an island constituted of the amorphous silicon layer 23 and the electrode contact layer 24 is formed in the thin film transistor 18. Specifically, the resist in parts other than where the island is to be formed are exposed to light using the third mask, and by conducting dry etching, unwanted parts of the amorphous silicon layer and the electrode contact layer are removed, and it is thus possible to form an island shown in FIG. 10C constituted of the amorphous silicon layer 23 and the electrode contact layer 24.

In the step of forming the first insulating film and the step of forming the semiconductor, the first insulating layer (gate insulating film 22), the first semiconductor layer (amorphous silicon layer 23), and the second semiconductor layer (electrode contact layer 24) are etched, and thus, the semiconductor layer (amorphous silicon layer 23) and the electrode contact layer 24 of the thin film transistor 18 are formed, and in the first insulating layer (gate insulating film 22), openings H1 and H4 are formed so as to expose the ends of the electrical wiring lines (auxiliary capacitance wiring line CS and gate wiring line G). In addition, patterning is conducted using the second mask in step S2, which is the step of forming the first insulating film, and the third mask in step 3, which is the step of forming the semiconductor. In other words, the openings H1 and H4 in the gate insulating film 22 and the island are formed by patterning using separate masks. As a result, the design of the manufacturing steps is more flexible compared to when using a halftone mask to form a resist with mutually different thicknesses, for example.

In the above example, after the semiconductor layer is formed on the gate insulating film 22, patterning is conducted on the gate insulating film 22 and the semiconductor layer using the third mask 52 as a mask, thus forming the openings H1 and H4, but the order of the patterning steps is not limited thereto. For example, it is possible to form the openings H1 and H4 by patterning the gate insulating film 22 using the second mask 52 after forming the island by patterning the semiconductor layer using the third mask 53.

### S4: Forming Second Conductive Layer

Next, as shown in step S4 of FIG. 9, the source electrode 18s and the channel region are formed.

Specifically, as shown on the left side of FIG. 10D, the titanium film 25a and the aluminum film 25b are deposited by sputtering, for example, and then patterning is conducted by photolithography using the fourth mask 54, wet etching, and resist removal and cleaning, thus forming the source electrode 18s constituted of the titanium film 25a and the aluminum film 25b. Also, as shown on the left side of FIG. 10D, the drain electrode 18d constituted of the titanium film 26a and the aluminum film 26b is formed at the same time as the source electrode 18s. In addition, by conducting dry etching, the electrode contact layer 24 above the channel region is removed, thus forming the electrode contact layers 24a and 24b, and the channel region.

As shown on the right side of FIG. 10D, at the same time as the source electrode 18s, the electrode member 30, which functions as the second conductive layer constituted of the titanium film 32a and the aluminum film 32b, is formed in the connective portion 29 by conducting patterning using the fourth mask 54. The electrode member 30 is formed so as to cover at least a portion of the edge of the opening H1, and so as to be directly connected to the end CS1 of the auxiliary capacitance wiring line CS in the opening H1. Also, as shown on the left side of FIG. 11D, at the same time as the source electrode 18s, the electrode connecting wiring line 26, which functions as the first conductive layer constituted of the titanium film 26a and the aluminum film 26b, is formed in the connective portion 34 on the gate insulating film 22 using the fourth mask 54. In addition, as shown on the right side of FIG. 11D, the intermediate electrode member 39, which functions as the second conductive layer, is formed in the gate terminal 38, at the same time as the source electrode 18s. The intermediate electrode member 39 is formed of a titanium film 39 and an aluminum film 39′, for example. The titanium film 39 and the aluminum film 39′ are formed so as to cover at least a portion of the edge of the opening H4, and so as to be directly connected to the end G1 of the gate wiring line G in the opening H4.

In the present embodiment, the electrode member 30, which is the second conductive layer, covers a portion of the opening H1 in the gate insulating film 22, but the entire opening H1 may be covered by the electrode member 30.

In other words, the titanium films 25a, 26a, 32a, and 39, and the aluminum films 25b, 26b, 32b, and 39′ are each simultaneously deposited and formed into a prescribed shape using the fourth mask 54. In other words, by conducting the step shown on the right side of FIG. 10D and the right side of FIG. 11D, the second conductive layer (electrode member 30 and intermediate electrode member 39) can be formed so as to cover at least a portion of the semiconductor layer (amorphous silicon layer 23), the electrode contact layer 24, and the edges H1a and H4a of the openings H1 and H4, and so as to be directly connected to the ends (CS1 and G1) of the electrical wiring lines (auxiliary capacitance wiring line CS and gate wiring line G) in the openings H1 and H4. By patterning the second conductive layer (titanium films 25a and 26a and aluminum films 25b and 26b) at the same time in the step shown on the left side of FIG. 10D, the source electrode 18s and the drain electrode 18d of the thin film transistor 18 can be formed.

Also, in the step shown on the right side of FIG. 10D, the auxiliary capacitance wiring line CS of the connective portion 29 is connected to the electrode member 30. In this manner, the auxiliary capacitance wiring line CS and the electrode member 30 are electrically connected at an early stage in the process and become more resistant to dielectric breakdown. For example, if a plurality of lines are electrically connected to the auxiliary capacitance wiring line CS in the latter half of the TFT manufacturing step (after ITO sputtering and the like take place), because dielectric breakdown is more likely to occur until the ITO is formed, there is a risk that wiring lines would break due to damage from an electrostatic discharge. Also, if the plurality of lines are electrically connected to the auxiliary capacitance wiring line CS after the ITO is formed, then the check for electrical connection occurs after the ITO is formed, and thus any problems with electrical connections are discovered after the last ITO forming step is finished. This causes an increase in costs due to the steps up to that point being wasted. As a countermeasure, in the step shown in FIG. 11D, the auxiliary capacitance wiring line CS and the electrode member 30 are connected electrically, thus preventing damage from such electrostatic discharge. This also mitigates increases in costs.

The specific thickness of the titanium films 25a, 26a, 32a, and 39 can be set to 30 to 150 nm, for example. Also, the specific thickness of the aluminum films 25b, 26b, 32b, and 39′ can be set to 100 to 400 nm, for example.

Instead of using the titanium films 25a, 26a, 32a, and 39, and the aluminum films 25b, 26b, 32b, and 39′ as described above, metals such as molybdenum or copper, and preferably metals that can be wet-etched and are not susceptible to corrosion can be used.

Also, a case as shown in FIG. 3 in which the intermediate electrode member 39 covers the entire opening H4 of the gate insulating film 22 in the gate terminal 38 was described, but the present embodiment is not limited thereto, and only at least a portion of the opening H4 needs to be covered by the intermediate electrode member 39 (the same applies to the source terminal 42). The intermediate electrode member 39 is provided to reduce the risk of a disconnection between the ITO, i.e., the third conductive layer, and the first conductive layer or the second conductive layer, which are connected in a manner described below. Such a disconnection is less likely to occur if the connection extends over just the interlayer insulating film and the protective layer instead of extending over the interlayer insulating film, the protective layer, and the gate insulating film (or the aluminum film 39′) all at once.

In addition, at the point in which the step of forming the second conductive layer is finished, the auxiliary capacitance wiring line CS, the gate wiring line G, and the source wiring line S are respectively connected to the electrode member 30, and the intermediate electrode members 39 and 43. In other words, the auxiliary capacitance wiring line CS, the gate wiring line G, and the source wiring line S are electrically connected to the corresponding electrode member 30 and intermediate electrode members 39 and 43 at an electrically floating state in the beginning stage of the manufacturing steps of the active matrix substrate 5. As a result, the active matrix substrate 5 of the present embodiment can greatly mitigate dielectric breakdown in the auxiliary capacitance wiring line CS, the gate wiring line G, and the source wiring line S, which greatly increases the manufacturing yield of the active matrix substrate 5.

### S5: Step of Forming Second Insulating Layer

Next, as shown in step S5 of FIG. 9, the protective layer 27 and the interlayer insulating film 28, which are examples of the second insulating layer, are formed.

Specifically, as shown on the left side of FIG. 10E, the protective layer 27 made of a silicon nitride (SiNₓ) is formed so as to cover the source electrode 18s and the drain electrode 18d by the CVD method, for example. The specific thickness of the protective layer 27 can be set to 100 to 700 nm, for example. The deposition temperature of the protective layer 27 can be set to 200 to 350° C. In order to prevent the film from being peeled off and the like, it is preferable that the protective layer 27 be deposited at a temperature lower than the temperature at which the gate insulating film 22, the amorphous silicon layer 23, and the electrode contact layer 24 are deposited (three layer deposition). Next, a coater is used in order to coat the protective layer 27 with a photosensitive interlayer insulating film material at a thickness of 3 to 5 μm, forming the interlayer insulating film 28. The protective layer 27 and the interlayer insulating film 28 can be formed at the same time so as to cover the electrode member 30 in the connective portion 29 shown on the right side of FIG. 10E. In addition, the protective layer 27 and the interlayer insulating film 28 can be formed at the same time in the connective portion 34 and the gate terminal 38 shown in FIG. 11E. As described above, by forming the protective layer 27 and the interlayer insulating film 28, the second insulating layer (protective layer 27 and interlayer insulating film 28) can be formed so as to cover the second conductive layer, which includes the source electrode 18s, the drain electrode 18d, the electrode member 30, and the intermediate electrode member 39.

When the protective layer 27 and the interlayer insulating film 28 are formed, as shown on the right side of FIG. 10E, the connective portion 29 is completed on the active matrix substrate 5.

In addition, after the interlayer insulating film 28 is patterned by photolithography using a fifth mask 55, dry etching is conducted, thus patterning the protective layer 27 and the interlayer insulating layer 28 in a prescribed shape. As a result, openings H5 and H6 can be formed in the second insulating layer (protective layer 27 and interlayer insulating film 28) so as to expose the connective portion between the end (G1) of the electrical wiring line (gate wiring line G) and the second conductive layer (intermediate electrode member 39).

Specifically, by conducting dry etching on the protective layer 27 in the gate terminal 38 as shown on the right side of FIG. 11E, the opening H5 is formed, and by conducting dry etching on the interlayer insulating film 28, the opening H6 is formed. In addition, in the gate terminal 38, by selectively wet-etching only the aluminum, the aluminum film 39′ (right side of FIG. 11D) exposed in the opening H5 is removed. As a result, the electrode member 40 made of ITO, which is deposited in the next step, is prevented from coming into contact with the aluminum film 39′, thus preventing the electrode member 40 from being corroded. If copper, titanium, or molybdenum, which does not corrode when in contact with ITO, is used for the wiring lines, this step is unnecessary.

In the connective portion 34, as shown on the left side of FIG. 11E, by dry-etching the protective layer 27, the opening H2 is formed, and by dry-etching the interlayer insulating film 28, the opening H3 is formed. In the connective portion 34, the titanium film 26a, which is the end of the electrode connecting wiring line 26, is provided so as to be exposed in the opening H2. In the connective portion 34, wet etching is conducted as in the gate terminal 38, thus removing the aluminum film 26b (left side of FIG. 11D) exposed in the opening H2. As a result, the pixel electrode 19 made of ITO deposited in a later step is prevented from coming into contact with the aluminum film 26b, thus preventing corrosion of the pixel electrode 19.

In the step of forming the openings H5 and H6, as shown in FIG. 3, the connective portion of the end (G1) of the gate wiring line G (first conductive layer) and the intermediate electrode member (second conductive layer) 39 is exposed in the openings H5 and H6. With this configuration, even if the second conductive layer is thinned out as a result of the developer, the remover, and the like in the photolithography step, it is possible for the second conductive layer to be reliably connected to the corresponding third conductive layer, which will be described below. This is particularly effective when using a metal with a relatively high susceptibility to corrosion, such as copper.

### S6: Step of Forming Third Conductive Layer

Next, as shown in step S6 of FIG. 9, the ITO, which is an example of the third conductive layer, is formed.

Specifically, as shown on the left side of FIG. 10F, ITO is deposited to a thickness of 50 to 200 nm onto the interlayer insulating film 28 by sputtering, for example, and then the ITO is patterned by photolithography using a sixth mask 56, wet etching, and resist removal and cleaning, thus forming the pixel electrode 19 on the interlayer insulating film 28.

In the connective portion 34, as shown on the right side of FIG. 11F, the pixel electrode 19 is directly connected to the titanium film 26a (one example of the second conductive layer) in the openings H2 and H3. Specifically, in the connective portion 34, the pixel electrode 19 is provided so as to cover at least a portion of the edge H2a of the opening H2 of the protective layer 27 and the edge H3a of the opening H3 of the interlayer insulating film 28, and so as to be directly connected to the titanium film 26a in the openings H2 and H3. As a result, the connective portion 34 is completed on the active matrix substrate 5.

In the gate terminal 38, as shown on the right side of FIG. 11F, the electrode member 40, which functions as the third conductive layer, is directly connected to the intermediate electrode member 39 (one example of second conductive layer) in the openings H5 and H6. Specifically, in the gate terminal 38, the electrode member 40 is provided so as to cover at least a part of the edge H5a of the opening H5 of the protective layer 27 and the edge H6a of the opening H6 of the interlayer insulating film 28, and so as to be directly connected to the intermediate electrode member 39 in the openings H5 and H6. With this configuration, the third conductive layer (electrode member 40) is formed so as to cover at least a portion of the edges (H5a and H6a) of the openings (H5 and H6) of the second insulating layer (protective layer 27 and interlayer insulating film 28), and so as to be directly connected to the second conductive layer (intermediate electrode member 39) in the openings (H5 and H6). The gate terminal 38 is then completed in the active matrix substrate 5.

In the active matrix substrate 5 of the present embodiment configured as stated above, in the connective portion 29, the end CS1 of the auxiliary capacitance wiring line CS (first conductive layer) is provided so as to protrude in the opening H1 provided in the gate insulating film 22 (first insulating layer). Also, in the connective portion 29, the electrode member 30 (second conductive layer) is provided so as to cover at least a portion of the edge H1a of the opening H1, and so as to be connected directly to the end CS1 of the auxiliary capacitance wiring line CS in the opening H1. With this configuration, it is possible to connect the electrode member 30 to the auxiliary capacitance wiring line CS without causing disconnections in the electrode member 30.

In the active matrix substrate 5 of the present embodiment, in the connecting section 34, the end 26a of the electrode connecting wiring line 26 (second conductive layer) is provided so as to protrude in the openings H2 and H3 respectively provided in the protective layer 27 and the interlayer insulating film 28 (second insulating layer). Also, in the connective portion 34, the pixel electrode 19 (third conductive layer) is provided so as to cover at least a portion of the edges H2a and H3a of the openings H2 and H3, and so as to be connected directly to the end 26a of the electrode connecting wiring line 26 in the openings H2 and H3. With this configuration, it is possible to connect the pixel electrode 19 to the electrode connecting wiring line 26 without causing disconnections in the pixel electrode 19.

In the active matrix substrate 5 of the present embodiment, in the gate terminal 38, the end G1 of the gate wiring line G (first conductive layer) is provided so as to protrude in the opening H4 provided in the gate insulating film 22 (first insulating layer). Also, in the gate terminal 38, the intermediate electrode member 39 (second conductive layer) is provided so as to cover at least a portion of the edge H4a of the opening H4, and so as to be connected directly to the end G1 of the gate wiring line G in the opening H4. With this configuration, it is possible to connect the intermediate electrode member 39 to the gate wiring line G without causing disconnections in the intermediate electrode member 39. In addition, in the gate terminal 38, the electrode member 40 (third conductive layer) is provided so as to cover at least a portion of the edges H5a and H6a of the openings H5 and H6, and so as to be connected directly to the intermediate electrode member 39 in the openings H5 and H6. With this configuration, it is possible to connect the electrode member 40 to the intermediate electrode member 39 without causing disconnections in the electrode member 40.

In the active matrix substrate 5 of the present embodiment, in the source terminal 42, the end S1 of the source wiring line S (first conductive layer) is provided so as to protrude in the opening H7 provided in the gate insulating film 22 (first insulating layer). Also, in the source terminal 42, the intermediate electrode member 43 (second conductive layer) is provided so as to cover at least a portion of the edge H7a of the opening H7, and so as to be connected directly to the end S1 of the source wiring line S in the opening H7. With this configuration, it is possible to connect the intermediate electrode member 43 to the source wiring line S without causing disconnections in the intermediate electrode member 43. In addition, in the source terminal 42, the electrode member 44 (third conductive layer) is provided so as to cover at least a portion of the edges H8a and H9a of the openings H8 and H9, and so as to be connected directly to the intermediate electrode member 43 in the openings H8 and H9. With this configuration, it is possible to connect the electrode member 44 to the intermediate electrode member 43 without causing disconnections in the electrode member 44.

As stated above, with the present embodiment, unlike conventional examples, it is possible to provide an active matrix substrate 5 in which a plurality of conductive layers that sandwich an insulating layer therebetween are reliably connected to each other.

The above-mentioned embodiment is all examples and not limiting. The technical scope of the present invention is defined by the claims, and all modifications within the scope defined by the claims are included within the technical scope of the present invention.

For example, in the above description, a case was described in which the present invention is applied to a transmissive liquid crystal display device, but the active matrix substrate of the present invention is not limited thereto, and can be applied to various types of display panels such as a transflective or reflective liquid crystal panel, an organic EL (electroluminescence) element, an inorganic EL element, or a field emission display.

Also, in the above description, an electrode connecting wiring line for connecting the drain electrode to the pixel electrode, an auxiliary capacitance wiring line, a gate wiring line, and a source wiring line are used for the first conductive layer, and a pixel electrode, an electrode member that connects the auxiliary capacitance wiring line to the source driver (driver part), an intermediate electrode member connected to the gate wiring line, and an intermediate electrode member connected to the source wiring line are used for the second conductive layer. However, the present invention is not limited to any particular configuration as long as the end of the first conductive layer is provided so as to protrude in the opening formed in the insulating layer, and the second conductive layer is provided so as to cover at least a portion of the edge of the opening, and so as to be connected directly to the end of the first conductive layer in the opening. Specifically, it is possible to use the common electrode and a common electrode wiring line connected thereto as the first and second conductive layer, for example.

Also, in the above description, a case was described in which the intermediate electrode member connected to the gate wiring line and the intermediate electrode member connected to the source wiring line are used as the second conductive layer, and the electrode member connected to the intermediate electrode member and the gate driver and the electrode member connected to the source driver are used as the third conductive layer. However, the present invention is not limited to any configuration as long as the second conductive layer is provided so as to cover at least a portion of the edge of the opening formed in the first insulating layer, and so as to be connected directly to the end of the first conductive layer in the opening formed in the first insulating layer, and as long as the third conductive layer is provided so as to cover at least a portion of the edge of the opening formed in the second insulating layer, and so as to be connected directly to the second conductive layer in the opening formed in the second insulating layer.

Also, in the above description, a configuration was described in which the gate insulating film is used as the first insulating layer, and the protective layer and the interlayer insulating film are used for the second insulating layer, but the first and second insulating layer of the present invention are not limited thereto, and the first and second insulating layers need only to be provided so as to cover the first and second conductive layers, respectively. For example, a configuration may be used in which only the protective layer is used as the second insulating layer.

Also, in the above description, a configuration was described in which the auxiliary capacitance wiring lines are connected to the source driver (driver part), but the present invention is not limited thereto. For example, it is possible to connect the auxiliary capacitance wiring lines to the gate driver, which functions as a driver part, or to connect the auxiliary capacitance wiring lines to a driver part (driver) that is specifically provided for the auxiliary capacitance wiring lines, thus generating capacitance.

### INDUSTRIAL APPLICABILITY

The present invention is applicable as an active matrix substrate in which a plurality of conductive layers that sandwich an insulating layer therebetween can be connected reliably to each other, and a manufacturing method therefor.

### DESCRIPTION OF REFERENCE CHARACTERS

5 active matrix substrate
5a substrate
16 source driver (driver part)
17 gate driver
18 thin film transistor
18g gate electrode
18s source electrode
18d drain electrode
19 pixel electrode
22 gate insulating film (first insulating layer)
26 electrode connecting wiring line (first conductive layer)
26a end
27 protective layer (second insulating layer)
28 interlayer insulating film (second insulating layer)
30 electrode member (second conductive layer)
39 intermediate electrode member (second conductive layer)
40 electrode member (third conductive layer)
43 intermediate electrode member (second conductive layer)
44 electrode member (third conductive layer)
G gate wiring line (first conductive layer, electrical wiring line)
G1 end
S source wiring line (first conductive layer, electrical wiring line)
S1 end
CS auxiliary capacitance wiring line (first conductive layer, electrical wiring line)
CS1 end
H1, H2, H3, H4, H5, H6, H7, H8, H9, opening
H1a, H2a, H3a, H4a, H5a, H6a, H7a, H8a, H9a edge (of opening)

1. A method for manufacturing an active matrix substrate having a thin film transistor, a first conductive layer, and a second conductive layer and a third conductive layer, which are connected to the first conductive layer, the method comprising:
patterning the first conductive layer using a first mask;
patterning a first insulating layer that covers the first conductive layer using a second mask so as to form an opening in the first insulating layer that exposes the first conductive layer;
patterning a semiconductor layer that covers the first conductive layer and the first insulating layer using a third mask;
patterning a second conductive layer that covers the first insulating layer using a fourth mask such that the first conductive layer and the second conductive layer are connected in the opening of the first insulating layer;
patterning a second insulating layer that covers the second conductive layer using a fifth mask so as to form an opening in the second insulating layer that exposes a connective portion of the first conductive layer and the second conductive layer; and
patterning a third conductive layer that covers the second insulating layer using a sixth mask such that the second conductive layer and the third conductive layer are connected in the opening of the second insulating layer.

2. The method for manufacturing an active matrix substrate according to claim 1,
wherein, in the step of patterning the first conductive layer, a gate electrode of the thin film transistor and an electrical wiring line are formed,
wherein, in the step of patterning the first insulating layer, an opening is formed in the first insulating layer, and an electrode contact layer is formed,
wherein, in the step of patterning the semiconductor layer, a semiconductor layer of the thin film transistor is formed, and
wherein, in the step of patterning the second conductive layer, the second conductive layer is formed so as to cover the semiconductor layer, the electrode contact layer, and at least a portion of an edge of the opening in the first insulating layer, such that a source electrode and a drain electrode in the thin film transistor are formed by etching the second conductive layer, and such that the electrical wiring line is connected to the second conductive layer in the opening.

3. The method for manufacturing an active matrix substrate according to claim 1,
wherein, in the step of patterning the first insulating layer, an opening is formed in the first insulating layer so as to expose an end of the first conductive layer, and
wherein, in the step of patterning the second conductive layer, the second conductive layer is patterned so as to cover at least a portion of an edge of the opening, and such that the end of the first conductive layer and the second conductive layer are directly connected to each other in the opening.

4. The method for manufacturing an active matrix substrate according to claim 1,
wherein, in the step of patterning the second insulating layer, an opening is formed in the second insulating layer so as to expose an end of the second conductive layer, and
wherein, in the step of patterning the third conductive layer, the third conductive layer is patterned so as to cover at least a portion of an edge of the opening, and such that the end of the second conductive layer and the third conductive layer are directly connected to each other in the opening.

5. The method for manufacturing an active matrix substrate according to claim 2,
wherein an auxiliary capacitance wiring line for generating auxiliary capacitance is used as the electrical wiring line,
wherein an electrode member that connects the auxiliary capacitance wiring line to a driver part to be connected to the auxiliary capacitance wiring line is used as the second conductive layer, and
wherein a connective portion between the auxiliary capacitance wiring line and the electrode member is formed in the step of patterning the second conductive layer.

6. The method for manufacturing an active matrix substrate according to claim 2,
wherein a gate wiring line connected to the gate electrode of the thin film transistor is used as the electrical wiring line,
wherein an intermediate electrode member connected to the gate wiring line is used as the second conductive layer,
wherein an electrode member connected to a gate driver and to the intermediate electrode member is used as the third conductive layer, and
wherein a gate terminal that connects the gate wiring line to the gate driver is formed in the step of patterning the third conductive layer.

7. The method for manufacturing an active matrix substrate according to claim 2,
wherein a source wiring line connected to the source electrode of the thin film transistor is used as the electrical wiring line,
wherein an intermediate electrode member connected to the source wiring line is used as the second conductive layer,
wherein an electrode member connected to a source driver and to the intermediate electrode member is used as the third conductive layer, and
wherein a source terminal that connects the source wiring line to the source driver is formed in the step of patterning the third conductive layer.

8. The method for manufacturing an active matrix substrate according to claim 1,
wherein an electrode connecting wiring line for connecting a drain electrode of the thin film transistor to a pixel electrode to be connected to the thin film transistor is formed of the second conductive layer, and
wherein a connective portion that connects the electrode connecting wiring line to the pixel electrode is formed of the third conductive layer.
